(19) United States
(12) Patent Application Publication
(10) Pub. No.: US 2025/0271320 A1
(43) Pub. Date: Aug. 28, 2025

(54) METHOD AND APPARATUS FOR DETECTION AND VISUAL ALERTING OF AN ELECTRICAL FAULT WITHIN A TANK

(71) Applicant: UBICQUIA, INC., FORT LAUDERDALE, FL (US)

(72) Inventors: Claudio Santiago Ribeiro, Evanston, IL (US); Elliott Earl Murray, Plantation, FL (US); Ivan Quiroz, Dallas, TX (US)

(21) Appl. No.: 19/064,665

(22) Filed: Feb. 26, 2025

Related U.S. Application Data
(60) Provisional application No. 63/558,086, filed on Feb. 26, 2024.
(60) Provisional application No. 63/558,594, filed on Feb. 27, 2024.

(51) Int. Cl. G01L 19/12; G01R 31/62; H01F 27/02

(52) U.S. Cl. CPC G01L 19/12; G01R 31/62; H01F 27/02

(57) ABSTRACT

A fault detection and alerting system, such as for detecting and visually alerting of an electrical fault within a tank, includes a pressure sensor and a visual alerting apparatus. The pressure sensor is configured for coupling to a pressure vent port or a pressure relief valve of the tank and produces/generates output signals corresponding to amounts of fluid pressure detected at the sensor's input. The visual alerting apparatus is operable to emit light when the pressure sensor output signal or its rate of change meets or exceeds a respective threshold, which may be preset or remotely configurable. In some embodiments, the system also includes a control device, where the visual alerting apparatus is positioned between the control device and the pressor sensor. When included, the control device analyzes the pressure sensor output signals and, when appropriate, provides one or more control signals to activate the visual alerting apparatus.

### CROSS-REFERENCE TO RELATED APPLICATIONS

The present application claims the benefit of and priority upon U.S. Provisional Patent Application No. 63/558,086, which was filed on Feb. 26, 2024, and is incorporated herein by this reference as if fully set forth herein. The present application also claims the benefit of and priority upon U.S. Provisional Patent Application No. 63/558,594, which was filed on Feb. 27, 2024, and is incorporated herein by this reference as if fully set forth herein.

### TECHNICAL FIELD

The present disclosure relates generally to detection of electrical power distribution transformer faults and, more particularly, to a method and apparatus for detection and visual alerting of an electrical fault within a tank, such as the tank of an electrical power distribution transformer.

### BACKGROUND

Distribution transformers are components of an electrical power transmission and distribution system. Such a system includes transmission substations, transmission lines, distribution substations, and distribution lines. A power source generates power, which is transmitted along high voltage (HV) transmission lines for long distances. Typical voltages found on HV transmission lines range from 69 kilovolts (kVAC) to in excess of 800 kVAC. The power signals are stepped down to medium voltage (MV) levels and then stepped down further to low voltage (LV) levels at distribution substations and transformers. LV power lines typically carry power signals having voltages ranging from about 100 VAC to residential customer premises and about 600 VAC to industrial or commercial customer premises.

In the United States, local distribution transformers typically feed anywhere from one to ten homes, depending upon the concentration of residential premises in a particular area. A power distribution system for a given area may include many distribution transformers. Thus, the monitoring costs, replacement costs, and maintenance costs for distribution transformers can be a significant factor in the cost of power distribution.

A number of factors adversely affect the life and operation of a distribution transformer. Such factors include overloading, lightning strikes, seal failures, winding failures, insulation oil breakdown, and so forth. Distribution transformer monitors (DTMs) are already used to monitor transformers in some power distribution systems. Although the DTMs monitor some events, they do not monitor all events that can significantly affect the life, operation, or viability of the distribution transformer. Available DTMs also fail to visibly warn line repair persons of hazardous conditions at a particular distribution transformer when the line repair persons go out to repair distribution transformers. In many instances, line repair teams re-energize distribution transformers that have gone offline. Re-energizing a distribution transformer by resetting a cut-out fuse may cause serious harm or even fatality under certain conditions. For example, a distribution transformer tank that is over-pressurized due to certain fault conditions can explode or have some other type of violent reaction if re-energized. Notably, when the distribution transformer's insulating oil breaks down from an internal arc or other gas-generating cause inside a distribution transformer, a gas bubble can form within the transformer tank causing air pressure in the tank to rise rapidly. Under such conditions, re-energizing the transformer could cause a violent reaction or even an explosion without taking further precautions, such as first venting the tank.

Current methods of warning repair persons in the field of high tank pressure conditions include the use of a mechanical fault detector (MFD), which is often referred to in the utility industry as a “turkey popper” type of fault detection device because dangerously high tank pressure causes a bright colored portion of the device to extend and remain out of the tank providing a visual alert to utility line repair personnel. Use of MFDs requires manual installation of the devices within distribution transformer tanks. Although MFDs are designed to prevent gas leaks or venting when the colored portion of the MFD pops out, undesired leaks may be caused merely by installing the MFDs within the tank, if such installation is not performed carefully. Additionally, at nighttime, a line repair person would likely need to have a flashlight to notice that the colored portion of the MFD was popped out.

All the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art.

### SUMMARY

According to some exemplary embodiments of the present disclosure, a fault detection and alerting system includes a pressure sensor and a visual alerting apparatus. The pressure sensor is configured for coupling to a pressure vent port and/or a pressure relief valve of a tank, such as, for example, an oil-filled tank of an electrical power distribution transformer, and is operable to produce output signals (e.g., voltages or currents) corresponding to amounts of fluid pressure detected at the sensor's input. The visual alerting apparatus is operable to emit light when the pressure sensor output signal or a rate of change of pressure sensor output signals meets or exceeds a respective threshold (e.g., a voltage or current threshold corresponding to a particular maximum safe tank pressure (e.g., about 7 pounds per square inch gauge (psig) or 43 kilopascals (kPa) (gauge)) to about 15 psig or 103 kPa (gauge) for single-phase aerial transformers) or a rate-of-change threshold corresponding to a rate of fluid pressure rise indicating a likely electrical or other fault within the tank (e.g., 0.5 to 1.0 psig per 10 milliseconds (ms)). The output signal threshold and/or the rate-of-change threshold may be preset and/or remotely configurable through a web-based or mobile application. The emitted light serves to notify or alert a user, such as tank service personnel or a utility line worker, that a fault (e.g., an electrical fault) has likely occurred within the tank. The fault detection and alerting system may alternatively include just the visual alerting apparatus where, for example, the visual alerting apparatus includes its own controller or processor, and the pressure sensor is already coupled to the pressure vent port and/or the pressure relief valve of the tank.

In some exemplary alternative embodiments, the fault detection and alerting system further includes a cable connected at one end to the pressure sensor and at an opposite end to the visual alerting apparatus. In such embodiments, the cable is configured to provide electrical paths for at least the pressure sensor output voltage and direct current (DC) power, where the DC power is supplied to at least the visual alerting apparatus and, if necessary, the pressure sensor. In other alternative embodiments, the visual alerting apparatus includes a rechargeable battery (e.g., a backup battery) and the DC power recharges the battery after a power outage, for example.

In further exemplary embodiments in which the tank is a tank of an electrical power distribution transformer, the fluid detected by the pressure sensor is air, and the light emitted by the visual alerting apparatus indicates an electrical fault has occurred within the tank. The electrical power distribution transformer may be a single-phase or a three-phase aerial distribution transformer, padmount distribution transformer, cabinet transformer, vault transformer, network transformer, or any other electrical power transformer.

According to further exemplary embodiments of the present disclosure, the visual alerting apparatus includes a housing, a connector at one end of the housing, and a light emitting module within the housing. In such embodiments, the light emitting module is operable to emit light when the pressure sensor output signal or the rate of change of pressure sensor output signals meets or exceeds its respective threshold. In some embodiments, the light emitting module includes one or more light emitting diodes (LEDs) or other long-life lamps and in other embodiments further includes a light diffuser.

According to other exemplary embodiments of the present disclosure, the fault detection and alerting system further includes a control device coupled to the visual alerting apparatus. In such embodiments, the control device includes a processor that is operable (e.g., in accordance with operating instructions or firmware stored in memory accessible by the processor) to receive the pressure sensor output signals, determine the rate of change of the pressure sensor output signals, compare the rate of change to a rate-of-change threshold, and generate one or more control signals when the rate of change meets or exceeds the rate-of-change threshold. According to these exemplary embodiments, the visual alerting apparatus is operable to emit its light responsive to receiving the one or more control signals from the control device. In some embodiments, the rate-of-change threshold is remotely configurable through a web-based or mobile application. According to one exemplary embodiment, the rate-of-change threshold is set to be equivalent to a tank fluid pressure rate of change in the range of about 0.5 to 1.0 psig per 10 ms (or, equivalently, 0.05 psig/ms to 0.10 psig/ms) or such other rate of change that corresponds to an undesired rate of fluid pressure rise within the distribution transformer tank.

In other exemplary embodiments in which the fault detection and alerting system includes a control device and the tank is a tank of an electrical power distribution transformer, the control device further includes a voltage sensing circuit. The voltage sensing circuit measures secondary voltages output from the electrical power distribution transformer.

In further exemplary embodiments in which the fault detection and alerting system includes a control device, the control device also includes a wireless modem (e.g., a cellular or other wireless technology modem). In such embodiments, the control device's processor is further operable to communicate one or more messages to a remote computer or computing platform, such as a cloud-based platform, via at least the wireless modem. The one or more messages include values of the pressure sensor output signals and, where the control device also includes a voltage sensing circuit, values of the secondary voltages output from the electrical power distribution transformer.

According to further exemplary embodiments of the present disclosure, the light emitted from the visual alerting apparatus illuminates according to an illumination schedule. The illumination schedule may be remotely configurable and include a duration of illumination (e.g., 3 days, 10 days, 30 days, etc.), a color of the light, a blinking pattern, a luminosity or intensity, and so forth. For example, according to some embodiments, the luminosity of the light emitted from the visual alerting apparatus is controlled or configured to be greater during daylight hours than during nighttime hours to enable service personnel to see the emitted light during any portion of the day.

In some exemplary alternative embodiments of the present disclosure, a fault detection and alerting system includes a pressure sensor, a control device, and a visual alerting apparatus. The pressure sensor is operable to produce output voltages corresponding to amounts of fluid pressure (e.g., air pressure) detected at the sensor's input. The pressure sensor is configured for coupling to at least one of a pressure vent port and a pressure relief valve of a tank. The control device includes a processor and a DC power source, such as an AC-to-DC power converter/regulator, one or more solar cells, or one or more batteries, that supplies DC power to the processor. The processor is operable to receive the pressure sensor output signals, compare the pressure sensor output signals or a rate(s) of change thereof to a respective threshold, and generate one or more control signals when a pressure sensor output signal or the rate of change of pressure sensor output signals meets or exceeds its respective threshold. In this case, the pressure sensor output signal threshold may be preset or remotely configured to correspond to a maximum safe tank pressure and the rate-of-change threshold may be preset or remotely configured to correspond to an undesired rate of fluid pressure rise within the tank. The visual alerting apparatus is positioned between the output of the pressure sensor and an input of the control device, and operable to emit light in response to the one or more control signals.

According to other exemplary embodiments of the present disclosure, a fault detection and alerting system includes at least a pressure sensor, a control device, and a visual alerting apparatus. The pressure sensor is configured for coupling to a pressure vent port and/or a pressure relief valve of a tank and is operable to produce output signals corresponding to an amount of fluid pressure detected at the sensor's input. The control device includes at least a processor and a DC power source (such as an AC-to-DC power converter/regulator, one or more solar cells, or one or more batteries) that supplies DC power to at least the processor. The control device processor is operable (e.g., in accordance with operating instructions or firmware stored in memory accessible by the processor) to receive the pressure sensor output signals (e.g., voltages or currents), compare each pressure sensor output signal to a threshold, and generate one or more control signals when the pressure sensor output signal meets or exceeds the threshold. In this case, the threshold may be preset or remotely configured to correspond to a maximum safe tank pressure. The visual alerting apparatus is positioned between the output of the pressure sensor and an input of the control device and operable to emit light in response to the one or more control signals from the processor. The emitted light serves to notify or alert a user, such as utility line workers, that a fault, such as an electrical fault, has likely occurred within the tank. In some embodiments, the control signals cause the visual alerting apparatus to emit light according to an illumination schedule, which may include a duration of illumination (e.g., 3 days, 10 days, 30 days, etc.), a color of the light, a blinking pattern, a luminosity of the light, an intensity of the light, and so forth. For example, according to some embodiments, the luminosity of the light emitted from the visual alerting apparatus is controlled or configured to be greater during daylight hours than during nighttime hours to enable service personnel to see the emitted light during any portion of the day.

In some exemplary alternative embodiments of the present disclosure in which any of the disclosed fault detection and alerting systems is used with an aerial electrical power distribution transformer, the visual alerting apparatus may be configured such that the light emitted therefrom is directed downwardly relative to the aerial position of the tank. Such a configuration of the visual alerting apparatus or at least a portion thereof, such as its light emitting module, enables service personnel at ground level or approaching the tank upwardly from the ground to readily see the light.

In other exemplary embodiments of the present disclosure, the control device further includes a light sensor (e.g., an optical sensor) configured to detect ambient light and the one or more control signals cause the visual alerting apparatus to emit light such that luminosity of the light is greater during daylight hours than during nighttime hours. In such embodiments, the level of luminosity is selected or adjusted based on the output of the light sensor.

According to alternative exemplary embodiments of the present disclosure, a fault detection and alerting system interfaces with a pressure sensor coupled to at least one of a pressure vent port and a pressure relief valve of a tank. The pressure sensor is operable to produce output signals corresponding to amounts of fluid pressure detected at the pressure sensor's input. According to such embodiments, the fault detection and alerting system includes a visual alerting apparatus, a control device, and a cable connecting the visual alerting apparatus to the pressure sensor. The visual alerting apparatus includes a housing, a light emitting module within the housing, and a connector at one end of the housing. The light emitting module is operable to emit light in response to one or more control signals. The control device includes a housing, a processor positioned within the control device housing, a DC power source positioned within the control device housing, and a connector that mates with the connector of the visual alerting apparatus. The processor is operable (e.g., in accordance with operating instructions or firmware stored in memory accessible by the processor) to receive the pressure sensor output signals, determine a rate of change of the pressure sensor output signals, compare the rate of change to a threshold, and generate the one or more control signals when the rate of change meets or exceeds the threshold. The DC power source supplies DC power to at least the processor and optionally to the visual alerting apparatus and the pressure sensor. The control device connector electrically connects (i) the one or more control signals and optionally DC power from the DC power source to the visual alerting apparatus, and (ii) the pressure sensor output signals to the control device. The cable is connected at one end to the pressure sensor and at an opposite end to the visual alerting apparatus. The cable is configured to provide electrical paths (e.g., wires) for at least the pressure sensor output signal and optionally for delivering the DC power to the pressure sensor.

According to other exemplary embodiments of the present disclosure, a method is provided for producing a visually perceivable alert responsive to a fault (electrical or otherwise) in an electrical power distribution transformer. The method includes detecting amounts of fluid pressure at a pressure vent port or a pressure relief valve of a tank of the electrical power distribution transformer, generating output signals (e.g. voltages or currents) based on the detected amounts of fluid pressure, determining rates of change of generated output signals, and emitting light when a generated output signal or a rate of change of generated output signals meets or exceeds a respective threshold. The method may be performed by a single device incorporating a pressure sensor, a processor, and a light emitting apparatus or by a combination of devices (e.g., separate pressure sensor, processor, and light emitting apparatus). In some embodiments, the light is emitted according to an illumination schedule. In such embodiments or other embodiments, the light is emitted at a location between a pressure sensor that detects the amounts of fluid pressure and generates the output signals and a control device that determines the rates of change and compares each generated output signal and each rate of change to its respective threshold. According to one exemplary embodiment, the threshold for the rate of change corresponds to an undesired rate of fluid pressure rise indicating a likely electrical or other fault within the tank (e.g., 0.5 to 1.0 psig per 10 ms). According to another exemplary embodiment, the pressure sensor signal threshold corresponds to a particular maximum safe tank pressure (e.g., about 7 psig or 43 kPa (gauge) to about 15 psig or 103 kPa (gauge) for single-phase aerial transformers).

According to further alternative embodiments of the present disclosure, a transformer fault detector (TFD) sensor is configured for coupling to a pressure sensor coupled to an electrical power distribution transformer. The TFD sensor includes a visual indicating apparatus integrated in-line with a cable connected between the TFD sensor and the pressure sensor, and a control device coupled to the visual indicating apparatus. The control device is configured to activate a visual alert of the visual indicating apparatus upon detection of a pressure sensor signal indicating a pressure level above a predetermined threshold or a pressure sensor signal indicating an abrupt pressure change indicative of fault within the power distribution transformer. In some embodiments, the pressure sensor signal is a voltage. In some embodiments, the visual indicating apparatus is positioned between the control device and the pressure sensor.

In other embodiments, the TFD sensor includes a rechargeable battery for powering the visual indicating apparatus independent of another power source. In further embodiments, the TFD sensor includes a rechargeable battery for powering the visual indicating apparatus and the control device independent of another power source.

In other embodiments, the control device activates the visual alert in a manner to conserve energy by operating according to a schedule. In some embodiments, the control device includes a processor, which may be on-board within a housing of the TFD sensor or external to a housing of the TFD sensor.

In some embodiments, the control device is a distribution transformer monitor residing external to a housing of the TED sensor but coupled to the TFD sensor.

### BRIEF DESCRIPTION OF THE DRAWINGS

Non-limiting and non-exhaustive embodiments are described with reference to the following drawings, wherein like reference numerals refer to like components or elements throughout the various views, unless otherwise specified. The sizes and relative positions of elements in the drawings are not necessarily drawn to scale. For example, the shapes of various elements are selected, enlarged, and positioned to improve drawing legibility. The particular shapes of the elements as drawn have been selected for ease of recognition in the drawings.

FIG. 1A illustrates an exploded view of a visual alerting apparatus in accordance with some embodiments of the present disclosure.

FIG. 1B illustrates an exploded view of a visual alerting apparatus in accordance with some alternative embodiments of the present disclosure.

FIG. 1C is a cutaway view along line 1C-1C of FIG. 1A illustrating an exemplary internal structure of the visual alerting apparatus of FIG. 1A.

FIG. 2A illustrates a block diagram of a fault detection and alerting system coupled to a pressure vent port and/or a pressure relief valve of a tank, in accordance with some exemplary embodiments of the present disclosure.

FIG. 2B illustrates a block diagram of a fault detection and alerting system coupled to a pressure vent port and/or a pressure relief valve sensor of a tank in accordance with some exemplary alternative embodiments of the present disclosure.

FIGS. 3A and 3B illustrate an exemplary fault detection and alerting system or transformer fault detector attached to a tank of an aerial power distribution transformer, in accordance with some embodiments of the present disclosure.

FIG. 4 illustrates an exemplary fault detection and alerting system or transformer fault detector attached to a tank of a padmount power distribution transformer, in accordance with other embodiments of the present disclosure.

FIG. 5 illustrates a block diagram of a control device for a fault detection and alerting system or transformer fault detector in accordance with some exemplary embodiments of the present disclosure.

FIG. 6 is a logic flow diagram of steps executed by a fault detection and alerting system or transformer fault detector in accordance with some exemplary embodiments of the present disclosure.

### DETAILED DESCRIPTION

In the following description, certain specific details are set forth to provide a thorough understanding of various disclosed embodiments. However, one skilled in the relevant art will recognize that embodiments may be practiced without one or more of these specific details, or with other methods, components, materials, etc. Additionally, well-known structures have been omitted or shown and described in reduced detail to avoid unnecessarily obscuring descriptions of the embodiments.

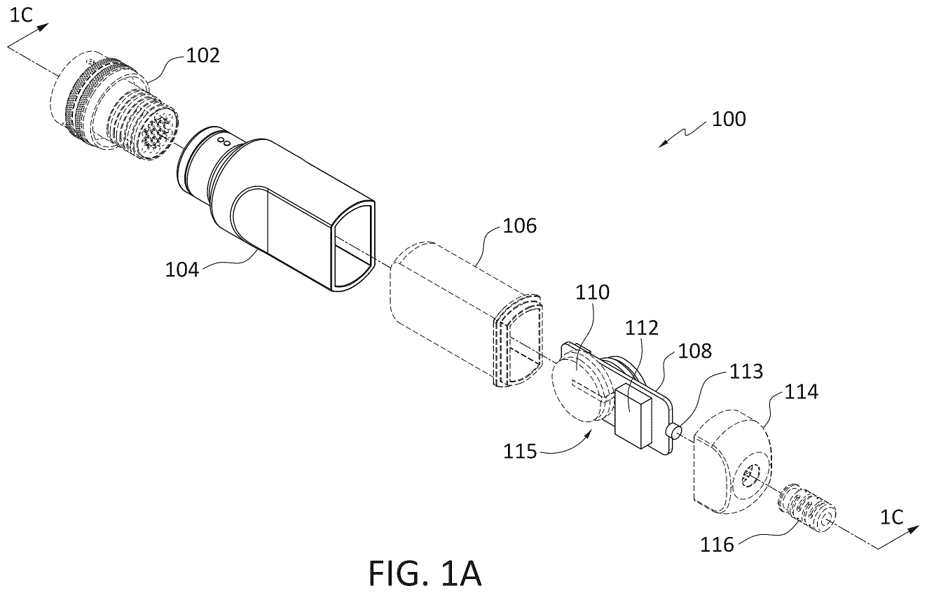

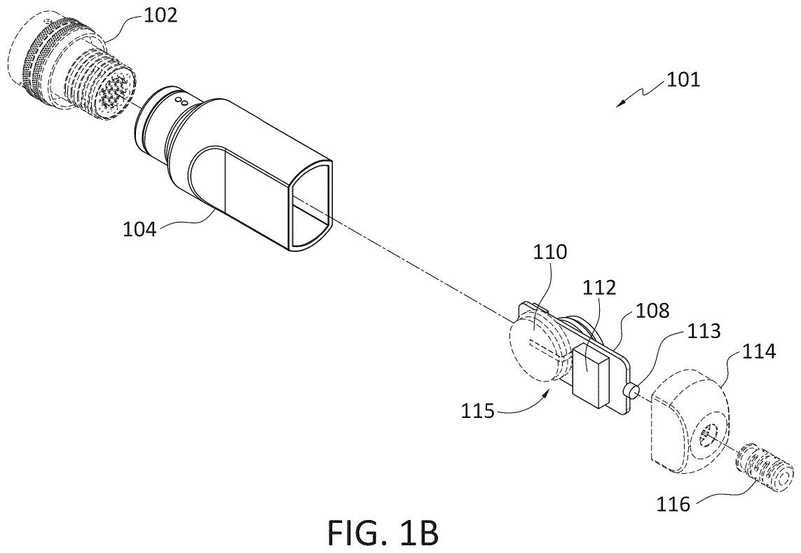

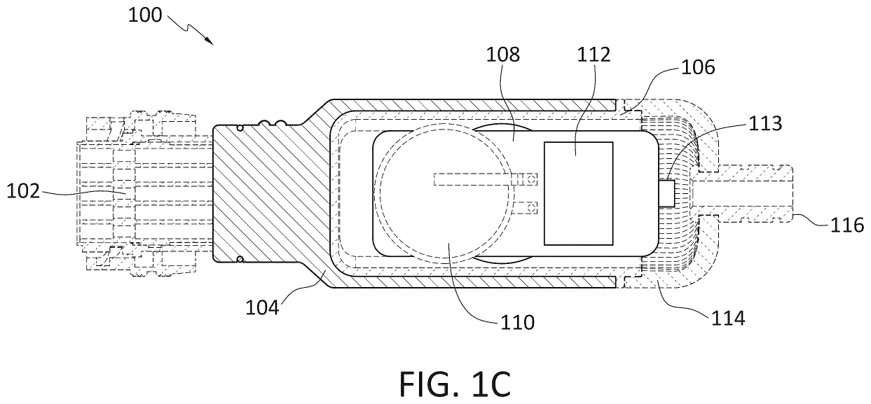

Referring to FIGS. 1-5, various views of exemplary fault detection and alerting systems and their components are shown. Such systems can detect pressure change-inducing faults, events, or other anomalies relating to a tank, such as the tank of an electrical power distribution transformer, based on output signals from a pressure sensor alone or in combination with other sensors, such as voltage sensors, current sensors, temperature sensors, or other parameter or performance sensors. Note that the parameter sensors contemplated within the embodiments of the present disclosure are not limited to pressure sensors as detailed here, but can include other sensors, such as cameras, current transformers, voltage sensors, or other devices that measure current, voltage, impedance, power factor, or other parameters useful in detecting potential system or component faults or events requiring further review, monitoring, maintenance, repair, replacement, or other desirable interventions. However, for purposes of the present disclosure, the focus of the description will be on fault detection and alerting systems that may be particularly useful for line workers who typically re-energize power distribution transformers by resetting or replacing cut-off or cut-out fuses. The visual alert provided by the disclosed systems and their visual alerting apparatus inform service personnel, such as line workers, of a potentially dangerous condition within a power distribution transformer, especially in connection with transformer re-energizing after an outage. The visual alerts provided by the disclosed systems give line workers warnings they will need to identify transformers that may need gas venting or possibly replacement before re-energizing and putting the transformer back online.

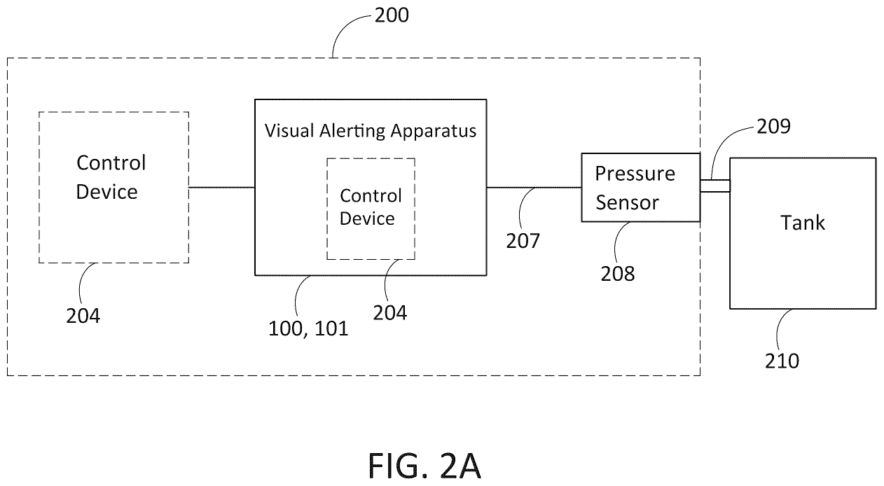

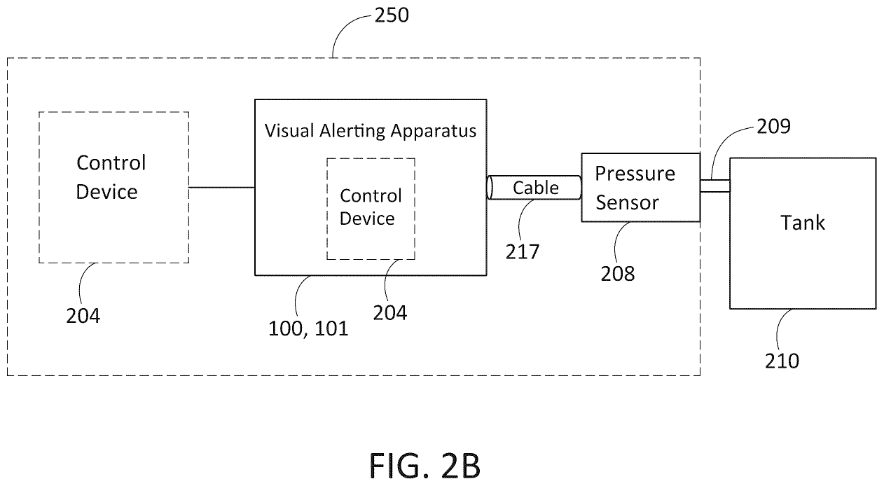

Referring to FIGS. 2A and 2B, a fault detection and alerting system 200, 250 includes or interfaces with a pressure sensor 208 coupled to a pressure vent port and/or a pressure relief valve 209 of a tank 210, such as the tank of an electrical power distribution transformer. The pressure sensor 208 outputs signals (voltages or currents) corresponding to amounts of fluid pressure detected at the sensor's input (i.e., the pressure vent port or the pressure relief valve 209). Each system 200, 250 shown in FIG. 2A and FIG. 2B includes a visual alerting apparatus 100, 101, the pressure sensor 208, and an optional control device 204, which may form part of or be separate from the visual alerting apparatus 100, 101. The main difference between the two systems 200, 250 shown in FIG. 2A and FIG. 2B is that in the system 250 illustrated in FIG. 2B, the interface 207 between the pressure sensor 208 and the visual alerting apparatus 100, 101 is a cable 217; whereas, in the system 200 illustrated in FIG. 2A, the interface 207 may be a connector, a cable, wires, a wireless interface (e.g., a short-range wireless connection), or any other interface.

FIGS. 1A-IC illustrate exemplary embodiments of the visual alerting apparatus 100, 101 used in the fault detection and alerting system 200, 250. According to the embodiment depicted in FIGS. 1A and 1C, the visual alerting apparatus 100 includes a housing (e.g., main housing 104), an optional electronics housing 106 that fits within the main housing 104, a light emitting module 115 positioned within the main housing 104 or the electronics housing 106, as applicable, an optional connector 102 at one end of the main housing 104 (e.g., for connecting to a mating connector of a control device 204), an optional transparent cover or cap 114 that covers one or more lamps/LEDs 113 (one shown for illustration purposes) and functions as a light diffuser, and an optional strain relief element 116, which interfaces with the cable 217, when used, to couple the visual alerting apparatus 100 to a distantly located pressure sensor 208. The light emitting module 115 includes one or more LEDs 113 or other lamps, an appropriate lamp driver circuit 112 (e.g., an LED driver), and an optional rechargeable or replaceable battery 110 (e.g., for backup power) assembled on and secured to a printed circuit board 108. The alternative visual alerting apparatus 101 depicted in FIG. 1B includes all the elements of the visual alerting apparatus 100 depicted in FIGS. 1A and 1C, except for two housings (e.g., the separate electronics housing 106). In all of the embodiments, the light emitting module 115 is operable to emit light when an output signal of the pressure sensor 208 or a rate of change of pressure sensor output signals meets or exceeds a respective threshold.

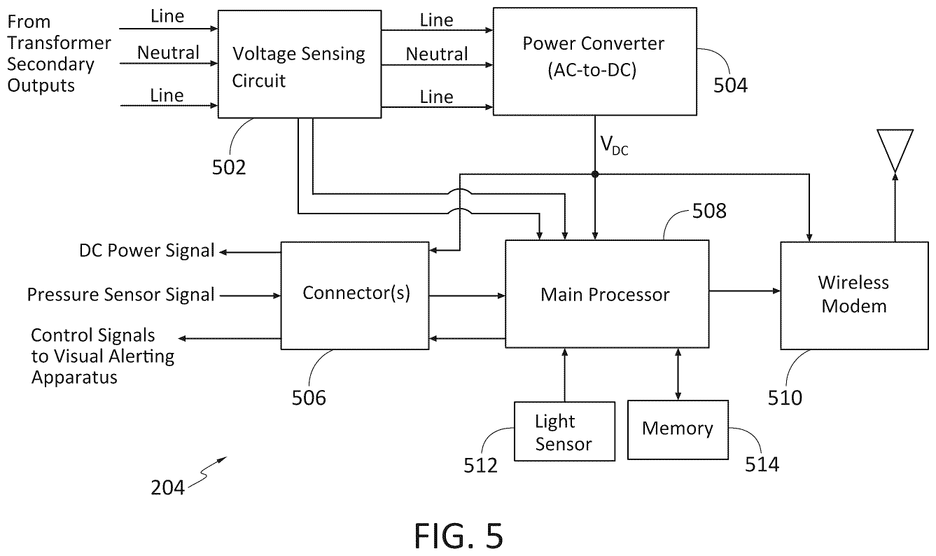

According to some embodiments, the fault detection and alerting system 200, 250 includes a control device 204 that the receives and analyzes the output signals from the pressure sensor 208 (e.g., via the interface 207 to the visual alerting apparatus 100, 101 and, when included, the cable 217). According to some exemplary embodiments, such as the embodiment illustrated in block diagram form in FIG. 5, the control device 204 includes, inter alia, a processor 508, memory 514 that stores the processor's operating instructions (firmware/software and configurable parameters (such as luminosity levels and schedule parameters for controlling the visual alerting apparatus 100, 101)), and a DC power source (such as, for example, an AC-to-DC power converter 504 that converts AC power received from secondary terminals of a distribution transformer 300, 400 to which the control device 204 is attached or at least electrically coupled to DC power for use by the processor 508, the memory 514, and other electrical components of the control device 204. The DC power supplied by the power converter 504 may also be supplied through the connector 102 to the electrical components of the visual alerting apparatus 100, 101, such as the lamp driver 112, the lamp/LED 113, and the rechargeable battery 110, and/or through the interface 207 (e.g., cable 217) to the power sensor 208. The control device 204 analyzes the pressure sensor output signals (e.g., voltages or currents) to determine whether the value (e.g., amplitude or magnitude) of each signal and/or the rate of change of the signals meet or exceed a respective threshold, and, if so, generates and supplies one or more control signals to the visual alerting apparatus 100, 101 (e.g., signals activating the lamp driver 112) to cause the visual alerting apparatus 100, 101 to emit light from the lamp/LED 113. The pressure sensor signal threshold may correspond to a maximum safe tank pressure (e.g., in the range of about 7 psig or 43 kilopascals (kPa) (gauge) to about 15 psig or 103 kPa (gauge) for single-phase aerial transformers) and the rate-of-change threshold may correspond to a rate of fluid pressure rise indicating a likely electrical or other fault within the tank (e.g., 0.5 to 1.0 psig per 10 ms). The instructions executed by the control device 204 may cause the processor 508 of the control device 204 to compare each pressure sensor signal parameter or characteristic (e.g., magnitude) to a threshold, compare the rate of change of the pressure signal parameters or characteristics (e.g., magnitudes) to a rate-of-change threshold, or both in order to determine whether to output the control signal(s) to the visual alerting apparatus 100, 101.

In some embodiments, the operating instructions stored in memory 514 include instructions for controlling the lamp driver 112 to illuminate the lamp 113 according to an illumination schedule. The illumination schedule may be a stored default schedule or remotely configurable and include a duration of illumination (e.g., 3 days, 10 days, 30 days, etc.), a color of the light (e.g., red), a blinking pattern, luminosity or intensity settings, and so forth. For example, according to some embodiments, the luminosity of the light emitted from the visual alerting apparatus 100, 101 is controlled or configured to be greater during daylight hours than during nighttime hours to enable service personnel to see the emitted light during any portion of the day. Alternatively, the illumination schedule and/or luminosity settings may be stored in local memory in the visual alerting apparatus 100, 101 such that the control signals supplied by the control device 204 cause the lamp driver 112 to execute the locally stored schedule or settings.

In some embodiments, the processor 508 of the control device 204 is the processor that is operable to receive the pressure sensor output signals, compare the pressure sensor output signals to a threshold, and generate the one or more control signals when the pressure sensor output signal magnitude meets or exceeds the threshold. In some embodiments, the system 200, 250 or the visual alerting apparatus 100, 101 further includes a DC power source such as a rechargeable battery 110 (or AC to DC power converter 504 in FIG. 5) positioned within the housing 104, 106 and operable to output DC power, a connector 102 that mates with a connector of the control device 204 and electrically connects (i) the one or more control signals and a DC power signal output by the DC power source 110, 504 to the visual alerting apparatus 100, 101, and (ii) the pressure sensor output voltage to the control device 204, and an interface 207, such as a set of wires contained in a cable 217, a connector, or a wireless interface (e.g., Bluetooth), connected at one end to the pressure sensor 208 and at an opposite end to the visual alerting device 100, 101. The interface 207 provides electrical paths for at least the pressure sensor output voltage and the DC power signal, where the DC power signal provides power to at least the visual alerting apparatus 100, 101 and the pressure sensor 208.

In some embodiments with reference to FIG. 1A, a fault detection and alerting system 200, 250, which may be generally referred to as a transformer fault detector or TFD, includes a visual alerting apparatus 100 containing a light emitting module 115 formed by a printed circuit board 108 having an LED driver 112 and an LED 113. The light emitting module 115 can include one or more rechargeable batteries 110 serving as a DC power source, the LED driver 112 or a processor or controller that includes the LED driver 112 and/or serves as the control device 204, and an LED 113 all mounted on the printed circuit board 108. The light emitting module 115 can further include a clear cap 114 that allows the light to flow or diffuse through the cap. The light emitting module 115 can be primarily enclosed by the clear cap 114 on one end and the housing 106 on the other end. As illustrated in FIG. 1A, the light emitting module 115 can also be enclosed within an electronics housing 106, which is enclosed within a larger, overmold housing 104. The clear cap 114 can have an opening for a connector (not shown in FIG. 1A) for the pressure sensor voltage coming from a pressure sensor via a cable 217, which can be coupled though a strain relief element 116. The visual alerting apparatus 100, 101 can further include another connector 102 that couples to a control device 204 external to the visual alerting apparatus 100, 101. FIG. 1C illustrates a cut view along line 1C-1C of FIG. 1A further illustrating all the elements shown in FIG. 1A.

In some embodiments as illustrated by the system 200 of FIG. 2A, a fault detection and alerting system 200 includes a pressure sensor 208 operable to produce a pressure sensor output voltage corresponding to an amount of fluid pressure detected at an input thereof, the pressure sensor 208 being configured for coupling to at least one of a pressure vent port and a pressure relief valve 209 of a tank 210, and a visual alerting apparatus 100 that includes a light emitting module 115 operable to emit light when the pressure sensor output voltage meets or exceeds a threshold. In some embodiments, the fault detection and alerting system 200 can just include the visual alerting apparatus 100, 101 that interfaces or operates with the pressure sensor 208 as explained above. In some embodiments, the light emitting module 115 can further include a control device 204, such as a processor. In some embodiments, a control device 204 can be outside the alerting apparatus 100. In some embodiments, the control device 204 is a separate unit coupled to the visual alerting apparatus 100, 101. In some embodiments, the system 200 can further include a cable 217, wire, or other interface 207 connected at one end to the pressure sensor 208 and at an opposite end to the visual alerting apparatus 100, 101, where the cable or wire 207 provides an electrical path for the pressure sensor output voltage signal.

In some embodiments with reference to an alternative fault detection and alerting system 250 of FIG. 2B which is similar to the system 200 of FIG. 2A, the fault detection and alerting system 250 includes a cable 217 as the interface between the pressure sensor 208 and the visual alerting apparatus 100, 101. In such embodiments, the cable 217 may be configured to provide electrical paths, such as wires, for at least the pressure sensor output voltage and a direct current (DC) power signal, where the DC power signal provides power to at least the visual alerting apparatus 100, 101 and the pressure sensor 208. In some embodiments, the visual alerting apparatus 100, 101 includes a rechargeable battery 110 where the DC power signal also provides power to the rechargeable battery 110.

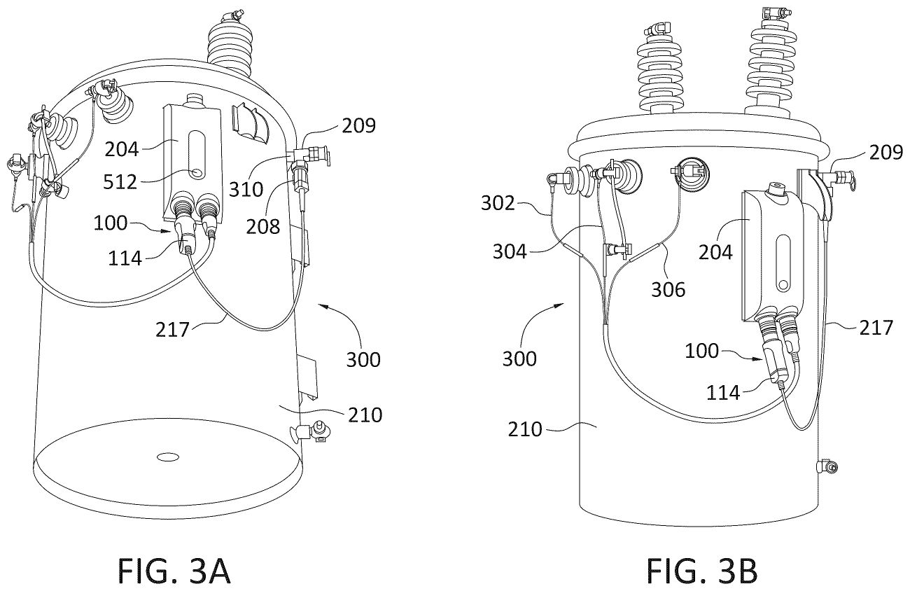

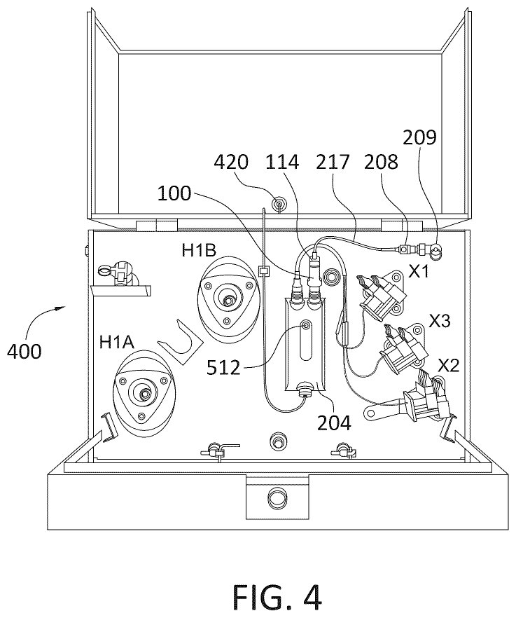

In some embodiments, the tank is a tank of an electrical power distribution transformer, where the fluid is air, and wherein the emitted light indicates a fault occurred within the tank. In some embodiments with reference to FIGS. 3A and 3B, the power distribution transformer is an aerial power distribution transformer 300 and in yet other embodiments as shown in FIG. 4, the power distribution transformer is a pad mounted transformer 400. The aerial power distribution transformer 300 can include secondary or lower voltage power lines 302, 304, and 306 (e.g., first line 302, neutral 304, and second line 306) that couple to a control device 204 as shown in FIGS. 3A and 3B to supply AC power to the control device 204, for example. In some embodiments, the aerial power distribution transformer 300 can further include a pressure vent port 310 and/or a pressure relief valve 209 coupled to a pressure sensor 208. In some embodiments, the pad mounted power distribution transformer 400 can further include a pressure vent port and/or a pressure relief valve 209 to which the pressure sensor 208 is coupled. As noted in FIGS. 2A and 2B, the pressure sensor can provide a signal or signals via the interface 207 (e.g., cable 217) to the light emitting module 115 of the alerting apparatus 100 causing a light or other visual indicator to shine through a clear cap 114 under certain pressure conditions or events.

In some embodiments, the visual alerting apparatus 100, 101 includes a housing 106 and/or 104, a connector 102 at one end of the housing, and a light emitting module 115 within the housing, the light emitting module being operable to emit light when the pressure sensor output voltage meets or exceeds a threshold. In some embodiments, the light emitting module 115 can include one or more light emitting diodes (LEDs) 113 and in other embodiments can further include a light diffuser as part of the clear cap 114.

In some embodiments with reference again to FIGS. 1A-2B, the fault detection and alerting system 200, 250 can further include a control device 204 coupled to the visual alerting apparatus 100, 101 where the control device 204 includes a processor operable to receive the pressure sensor output voltage, compare the pressure sensor output voltage to a threshold, and generate the control signal when the pressure sensor output voltage meets or exceeds the threshold.

Note, in various embodiments, the fault detection and alerting system 200 can include in one embodiment just the visual alerting apparatus 100, 101 and the control device 204 as shown in FIG. 2B. In yet another embodiment, the fault detection and alerting system 250 can include the visual alerting apparatus 100, 101, the control device 204, and the cable 217. In still yet another embodiment, the fault detection and alerting system 250 can include the visual alerting apparatus 100, 101, the control device 204, the cable 217, and the pressure sensor 208.

Referring to FIG. 2A, in some embodiments the fault detection and alerting system 200, 250 can include the visual alerting apparatus 100, 101 and a control device 204 external to the visual alerting apparatus 100, 101. In yet another embodiment, the fault detection and alerting system 250 can include the visual alerting apparatus 100, 101, the control device 204, and the cable 207. In yet another embodiment, the fault detection and alerting system 250 can include the visual alerting apparatus 100, 101, the control device 204, and the cable 207. In still yet another embodiment, the fault detection and alerting system 250 can include the visual alerting apparatus 100, 101, the control device 204, the cable 207, and the pressure sensor 208.

In some embodiments with additional reference to the control device 204 of FIG. 5, the tank 210 is a tank of an electrical power distribution transformer where the control device 204 (see FIG. 5) further includes a voltage sensing circuit 502 that measures secondary voltages output from the electrical power distribution transformer 300, 400.

In some embodiments, the control device 204 further includes a wireless modem 510 where the processor is further operable to communicate one or more messages to a remote computer via at least the wireless modem 510 (e.g., via its associated antenna, such as antenna 420, for example), the one or more messages including values of the pressure sensor output voltage (received via connector(s) 506 and values of the secondary voltages via voltage sensing circuit 502, power converter 504, and optionally processor 508).

In some embodiments, the light emitted from the visual alerting apparatus 100, 101 illuminates according to an illumination schedule. This can be done to conserve energy and extend the period of time that the rechargeable battery can power and operate the visual alerting apparatus 100, 101 in the event of a power outage affecting the control device 204. This can be particularly important with transformers located in remote areas where it can take a longer period of time for a line person to get to the power transformer to service it.

In some embodiments, luminosity of the light emitted from the visual alerting apparatus 100, 101 is greater during daylight hours than during nighttime hours. This can be done for several purposes including the purpose of conserving energy. Further, the differential luminosity setting can provide greater visibility to the visual alerting apparatus enabling a line worker to more easily recognize the condition of the transformer during the day as the light will be more conspicuous during night-time even with lower luminosity.

In some embodiments with reference again to a system 200 of FIG. 2A, the fault detection and alerting system 200 can include a pressure sensor 208 operable to produce a pressure sensor output voltage corresponding to an amount of fluid pressure detected at an input thereof, the pressure sensor 208 being configured for coupling to at least one of a pressure vent port and/or a pressure relief valve 209 of a tank 210, and a control device 204 including a processor. The processor (such as the main processor 508 shown in FIG. 5) can be operable to receive the pressure sensor output voltage, compare the pressure sensor output voltage to a threshold, and generate one or more control signals when the pressure sensor output voltage meets or exceeds the threshold. Further referring to FIG. 5, a control device 204 can further include a direct current (DC) power source (via power converter 504 or rechargeable battery 110) operable to output at least one DC power signal and a visual alerting apparatus 100, 101 positioned between an output of the pressure sensor 208 and an input of the control device 204, the visual alerting apparatus 100, 101 operable to emit light in response to the one or more control signals. In one embodiment, the control signals are shown being sent to the visual alerting apparatus 100, 101 via the main processor 508 and connector(s) 506 as shown in FIG. 5.

In some embodiments, the tank is a tank of an aerial electrical power distribution transformer 300 as shown in FIGS. 3A and 3B where the visual alerting apparatus 100, 101 includes a light emitting module 115 configured such that the emitted light is directed downwardly relative to an aerial position of the tank. In one embodiment as shown in FIGS. 3A and 3B, the visual alerting apparatus 100, 101 is directed downwardly by connecting the module to a bottom portion of the control device 204 as shown. This downward configuration makes it easier for a line worker to spot the light emitted from the light emitting module 115 of the visual alerting device 100, 101 because the line worker will likely approach and initially inspect the transformer 300 from below. As noted previously, the emitted light can indicate that a fault occurred within the tank. In some embodiments, the light emitted from the visual alerting apparatus 100, 101 illuminates according to an illumination schedule. In the case of a pad mounted transformer as shown in FIG. 4, the visual alerting apparatus 100, 101 can be directed in an upward direction by connecting the alerting apparatus 100 to a top oriented portion (such as a connector) of the control device 204. In some embodiments, the light sensor 512 can be used in conjunction with the overall system to conserve battery power by generally only enabling or activating the visual alerting apparatus 100, 101 with greater luminosity when the transformer hatch is open and exposed to ambient light. Otherwise, the visually alerting apparatus 100, 101 will use a lower luminosity level.

In some embodiments with reference to FIG. 5, the control device 204 further includes a light sensor 512 (e.g., an optical sensor) configured to detect ambient light and the one or more control signals cause the visual alerting apparatus 100, 101 to emit light such that luminosity of the light (such as LED 113) is greater during daylight hours than during nighttime hours. The control device can also include a memory 514 coupled to the processor 508 to serve as a storage for all types of data useful in the operation of a control device or in a fault detection and alerting system 200, 250 including threshold levels, pressure sensor voltage readings, secondary voltage level readings, rechargeable battery voltage readings, DC power signal readings, lighting schedules or sequences, lighting luminosity levels, and the like.

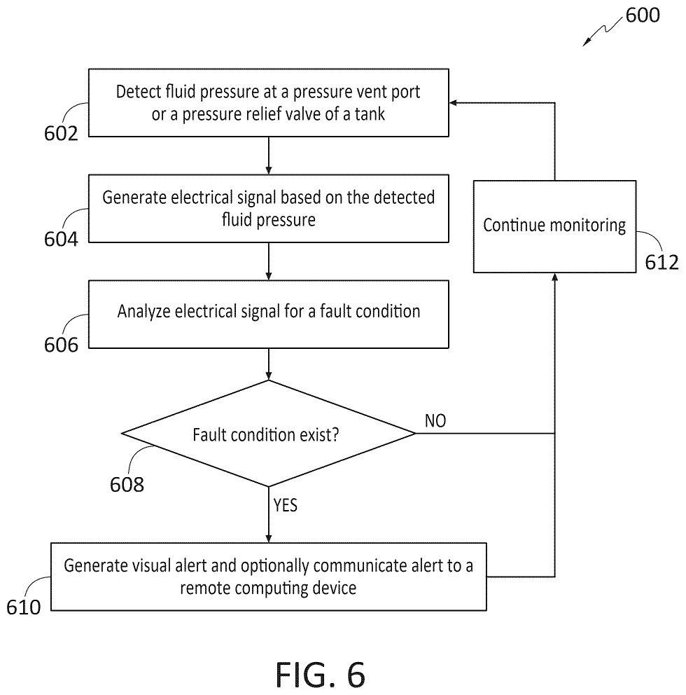

FIG. 6 is a logic flow diagram 600 of steps executed by a fault detection and alerting system 200, 250 to produce a visually perceivable alert responsive to a fault in an electrical power distribution transformer 300, 400, in accordance with some exemplary embodiments of the present disclosure. According to the logic flow, the system 200, 250 (e.g., a pressure sensor 204 of the system 200, 250) detects (602) amounts of fluid pressure (e.g., air pressure) at a pressure vent port or a pressure relief valve 209 of the transformer tank 210 and generates (604) electrical output signals (voltage or current) based on (e.g., corresponding to) the detected amounts of fluid pressure. The system 200, 250 (e.g., a processor 508 of the system 200, 250 or its control device 204) analyzes (606) the output signals for an indication of a fault condition. For example, the system processor 508 may determine a rate of change of the pressure sensor output signals and compare it to a rate-of-change threshold, which may be set to a rate of change that corresponds to an undesired rate of fluid pressure rise within the distribution transformer tank 210 or a rate of fluid pressure rise indicative of other irregular, abnormal, or faulty operation of the transformer 300, 400. Alternatively or additionally, the system processor 508 may compare magnitudes of the pressure sensor output signals to a signal magnitude threshold, such as a signal magnitude corresponding to a maximum safe tank pressure, to determine whether a pressure sensor signal magnitude meets or exceeds such signal magnitude threshold. When, based upon analysis of the pressure sensor output signals, the system 200, 250 determines (608) a fault condition exists (e.g., the rate of change of the pressure sensor signal magnitudes meet or exceed the rate-of-change threshold and/or a pressure sensor signal magnitude meets or exceeds the signal magnitude threshold), the system 200, 250 (e.g., the visual alerting apparatus 100, 101) generates (610) a visual alert by illuminating the lamp/LED 113 and optionally communicates the alert and optionally the data upon which the alert is based to a remote computing device or platform via a wireless modem 510. In some embodiments, the light is emitted between the pressure 209 and the control device 204 of the system 200, 250. When, based upon analysis of the pressure sensor output signals, the system 200, 250 determines (608) a fault condition does not exist, the system 200, 250 continues (612) monitoring the pressure sensor output signals. In some embodiments, the pressure (e.g., pressure-related voltage) may be monitored for other potential fault conditions, such as when an abrupt pressure change occurs (even when not exceeding a threshold).

In some embodiments with references to FIGS. 1A-6, a transformer internal fault detector sensor (TFD) 100 configured to couple to a pressure sensor 208 coupled to a tank (100) of a distribution power transformer 300, 400 can include a visual indicating apparatus 100, 101 integrated in-line with a cable 207, 217 connected between the TFD 100 and the pressure sensor 208, and a control device 204 coupled to the visual indicating apparatus 100, 101, where the control device is configured to activate a visual alert on the visual indicating apparatus 100, 101 upon detection by the pressure sensor 208 of a measure of a pressure level above a predetermined threshold or upon a measure of an abrupt pressure change indicative of fault within a power distribution transformer. In some embodiments, the measure of the pressure level can be a voltage.

In some embodiments, the visual indicating apparatus 100, 101 is integrated in-line with the cable 217 connected between the control device 204 and a pressure relief valve 209.

In some embodiments, the TFD 100 further includes a rechargeable battery 110 for powering the visual indicating apparatus 100, 101 independent of another power source.

In some embodiments, the TFD 100 further includes a rechargeable battery 110 for powering the visual indicating apparatus 100, 101 and control device 204 independent of another power source.

In some embodiments, the TFD 100 further includes a rechargeable battery 110 for powering the visual indicating apparatus 100, 101 and control device 204 independent of another power source and where the visual alert 113 activates in a manner to conserve energy by operating according to a schedule.

In some embodiments, the control device 204 includes an on-board processor within a housing 104, 106 of the transformer internal fault detector 100. Note that the processor or control device in certain embodiments is referred to interchangeably.

In some embodiments, the control device 204 includes a processor or external to a housing (104 or 106) of the transformer internal fault detector 100.

In some embodiments, the control device 204 operates as a distribution transformer monitor (DTM) residing external to a housing of the transformer internal fault detector 100 but coupled to the transformer internal fault detector.

The embodiments herein can have their own communication links but could also leverage the existing remote over-the-air (OTA) capabilities supported by certain DTM devices. This OTA capability, when supported, allows the operator to perform remote analysis as well as configuration updates of the DTM device(s) (or the Rogowski coil related monitoring equipment or the pressure sensors) without the need for costly truck rolls or unit replacement. By supporting OTA firmware updates and upgrades, providers can progressively broaden and deepen the suite of data points captured by the DTM device and/or other devices operating independent of the DTM device. All the data collected can be transmitted either in a wired fashion or via a wireless connection.

In the absence of any specific clarification related to its express use in a particular context, where the terms “substantial” or “about” in any grammatical form are used as modifiers in the present disclosure and any appended claims (e.g., to modify a structure, a dimension, a measurement, or some other characteristic), it is understood that the characteristic may vary by up to 30 percent. For example, a small cell networking device may be described as being mounted “substantially vertical,” In these cases, a device that is mounted exactly vertical is mounted along a “Y” axis and a “X” axis that is normal (i.e., 90 degrees or at right angle) to a plane or line formed by a “Z” axis. Different from the exact precision of the term, “vertical,” and the use of “substantially” or “about” to modify the characteristic permits a variance of the particular characteristic by up to 30 percent.

The terms “include” and “comprise” as well as derivatives thereof, in all of their syntactic contexts, are to be construed without limitation in an open, inclusive sense, (e.g., “including, but not limited to”). The term “or,” is inclusive, meaning “and/or.” The phrases “associated with” and “associated therewith,” as well as derivatives thereof, can be understood as meaning to include, be included within, interconnect with, contain, be contained within, connect to or with, couple to or with, be communicable with, cooperate with, interleave, juxtapose, be proximate to, be bound to or with, have, have a property of, or the like.

Unless the context requires otherwise, throughout the specification and claims which follow, the word “comprise” and variations thereof, such as, “comprises” and “comprising,” are to be construed in an open, inclusive sense (e.g., “including, but not limited to”).

Reference throughout this specification to “one embodiment” or “an embodiment” or “some embodiments” and variations thereof mean that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content and context clearly dictates otherwise. It should also be noted that the conjunctive terms, “and” and “or” are generally employed in the broadest sense to include “and/or” unless the content and context clearly dictates inclusivity or exclusivity as the case may be. In addition, the composition of “and” and “or” when recited herein as “and/or” is intended to encompass an embodiment that includes all of the associated items and one or more other alternative embodiments that include fewer than all of the associated items.

As the context may require in this disclosure, except as the context may dictate otherwise, the singular shall mean the plural and vice versa. All pronouns shall mean and include the person, entity, firm or corporation to which they relate. Also, the masculine shall mean the feminine and vice versa.

When so arranged as described herein, each computing device may be transformed from a generic and unspecific computing device to a combination device comprising hardware and software configured for a specific and particular purpose. When so arranged as described herein, to the extent that any of the inventive concepts described herein are found by a body of competent adjudication to be subsumed in an abstract idea, the ordered combination of elements and limitations are expressly presented to provide a requisite inventive concept by transforming the abstract idea into a tangible and concrete practical application of that abstract idea.

The various embodiments described above can be combined to provide further embodiments. Aspects of the embodiments can be modified, if necessary to employ concepts of the various patents, application and publications to provide further embodiments.

What is claimed is:

1. A fault detection and alerting system comprising:
a pressure sensor operable to produce output signals corresponding to amounts of fluid pressure detected at an input thereof, the pressure sensor being configured for coupling to at least one of a pressure vent port and a pressure relief valve of a tank; and
a visual alerting apparatus operable to emit light when a pressure sensor output signal or a rate of change of pressure sensor output signals meets or exceeds a respective threshold.

2. The fault detection and alerting system of claim 1, further comprising:
a cable connected at one end to the pressure sensor and at an opposite end to the visual alerting apparatus, the cable being configured to provide electrical paths for at least the pressure sensor output signals and direct current (DC) power, wherein the DC power is supplied to at least the visual alerting apparatus.

3. The fault detection and alerting system of claim 2, wherein the visual alerting apparatus includes a rechargeable battery and wherein the DC power recharges the rechargeable battery.

4. The fault detection and alerting system of claim 1, wherein the tank is a tank of an electrical power distribution transformer, wherein the fluid is air, and wherein the emitted light indicates an electrical fault has occurred within the tank.

5. The fault detection and alerting system of claim 1, wherein the visual alerting apparatus includes:
a housing;
a connector at one end of the housing; and
a light emitting module within the housing, the light emitting module being operable to emit light when the pressure sensor output signal or the rate of change meets or exceeds the respective threshold.

6. The fault detection and alerting system of claim 1, wherein the visual alerting apparatus is operable to emit the light responsive to receiving one or more control signals, the fault detection and alerting system further comprising:
a control device coupled to the visual alerting apparatus, the control device including:
a processor operable to:
receive pressure sensor output signals;
determine the rate of change of the pressure sensor output signals;
compare the rate of change to a rate-of-change threshold; and
generate the one or more control signals when the rate of change meets or exceeds the rate-of-change threshold.

7. The fault detection and alerting system of claim 6, wherein the tank is a tank of an electrical power distribution transformer and wherein the control device further includes a voltage sensing circuit that measures secondary voltages output from the electrical power distribution transformer.

8. The fault detection and alerting system of claim 7, wherein the control device further includes a wireless modem and wherein the processor is further operable to communicate one or more messages to a remote computing platform via at least the wireless modem, the one or more messages including values of the pressure sensor output signals and values of the secondary voltages.

9. The fault detection and alerting system of claim 1, wherein the light emitted from the visual alerting apparatus illuminates according to an illumination schedule.

10. The fault detection and alerting system of claim 1, wherein luminosity of the light emitted from the visual alerting apparatus is greater during daylight hours than during nighttime hours.

11. The fault detection and alerting system of claim 1, wherein the respective threshold for the rate of change corresponds to an undesired rate of fluid pressure rise within the tank.

12. A fault detection and alerting system comprising:
a pressure sensor operable to produce pressure sensor output signals corresponding to amounts of fluid pressure detected at an input thereof, the pressure sensor being configured for coupling to at least one of a pressure vent port and a pressure relief valve of a tank;
a control device including:
a processor operable to:
receive the pressure sensor output signals;
compare each pressure sensor output signal to a signal threshold;
determine a rate of change of the pressure sensor output signals;
compare the rate of change to a rate-of-change threshold; and
generate one or more control signals when a pressure sensor output signal meets or exceeds the sensor threshold or the rate of change meets or exceeds the rate-of-change threshold; and
a direct current (DC) power source that supplies DC power to at least the processor; and
a visual alerting apparatus positioned between an output of the pressure sensor and an input of the control device, the visual alerting apparatus operable to emit light in response to the one or more control signals.

13. The fault detection and alerting system of claim 12, wherein the tank is a tank of an aerial electrical power distribution transformer and wherein at least a portion of the visual alerting apparatus is configured such that the emitted light is directed downwardly relative to an aerial position of the tank.

14. The fault detection and alerting system of claim 12, wherein the tank is a tank of an electrical power distribution transformer, wherein the fluid is air, and wherein the emitted light indicates an electrical fault has occurred within the tank.

15. The fault detection and alerting system of claim 12, wherein the light emitted from the visual alerting apparatus illuminates according to an illumination schedule.

16. The fault detection and alerting system of claim 12, wherein the rate-of-change threshold corresponds to an undesired rate of fluid pressure rise within the tank.

17. A fault detection and alerting system that interfaces with a pressure sensor coupled to at least one of a pressure vent port and a pressure relief valve of a tank, the pressure sensor being operable to produce output signals corresponding to amounts of fluid pressure detected at an input thereof, the fault detection and alerting system comprising:
a visual alerting apparatus including a first housing, a light emitting module within the first housing, and a first connector at one end of the first housing, the light emitting module operable to emit light in response to one or more control signals;
a control device including:
a second housing;
a processor positioned within the second housing and operable to:
receive the pressure sensor output signals;
determine a rate of change of the pressure sensor output signals;
compare the rate of change to a threshold; and
generate one or more control signals when the rate of change meets or exceeds the threshold; and
a direct current (DC) power source positioned within the second housing and supplying DC power to the processor; and
a second connector that mates with the first connector and electrically connects (i) the one or more control signals and the DC power to the visual alerting apparatus, and (ii) the pressure sensor output signals to the control device; and
a cable connected at one end to the pressure sensor and at an opposite end to the visual alerting apparatus, the cable being configured to provide an electrical path for at least the pressure sensor output signals.

18. A method for producing a visually perceivable alert responsive to a fault in an electrical power distribution transformer, the method comprising:
detecting amounts of fluid pressure at one of a pressure vent port and a pressure relief valve of a tank of the electrical power distribution transformer;
generating output signals based on the detected amounts of fluid pressure;
determining rates of change of the generated output signals; and
emitting light when a generated output signal or a rate of change of generated output signals meets or exceeds a respective threshold.

19. The method of claim 18, wherein the respective threshold for the rate of change corresponds to an undesired rate of fluid pressure rise within the tank.

20. The method of claim 18, wherein the step of emitting light includes emitting light between a pressure sensor that detects the amounts of fluid pressure and generates the output signals and a control device that determines the rates of change and compares each generated output signal and each rate of change to the respective threshold.
